(19) United States
(12) Patent Application Publication
(10) Pub. No.: US 2012/0188819 A1
(43) Pub. Date: Jul. 26, 2012

(54) METHODS AND SYSTEMS FOR MEMS CMOS PROGRAMMABLE MEMORIES AND RELATED DEVICES

(75) Inventors: Josep Montanya Silvestre, Rubi (ES); Marco Antonio Llamas Morote, Viladecans (ES)

(73) Assignee: Baolab Microsystems SL, Terrassa (ES)

(21) Appl. No.: 13/356,178

(22) Filed: Jan. 23, 2012

Related U.S. Application Data
(60) Provisional application No. 61/435,057, filed on Jan. 21, 2011.

(51) Int. Cl. G11C 11/34; H01H 37/76; H01L 21/82

(52) U.S. Cl. 365/174; 438/128; 327/525; 257/E21.632

(57) ABSTRACT

Systems and methods for CMOS-based MEMS programmable memories are described. In one aspect, the systems and methods provide for a programmable memory having multiple memory cells. Each memory cell includes an electrode disposed within the memory cell, and a conductor material having two ends disposed proximate to the electrode. The programmable memory provides means for applying a voltage between the electrode and the conductor material, e.g., a voltage source. The applied voltage generates an electrostatic force sufficient to permanently alter the conductor material, thereby programming the memory cell.

### CROSS REFERENCE TO RELATED APPLICATIONS

This application claims priority to U.S. Provisional Patent Application No. 61/435,057, filed Jan. 21, 2011, entitled “Methods and Systems for Fabrication of MEMS CMOS Devices,” hereby incorporated by reference in its entirety.

### BACKGROUND

Memory cells are typically embedded in current electronic devices, e.g., computers, cell phones, cameras, and games. They may be classified as either volatile or non-volatile memory cells. A volatile memory cell stores data only as long as power is provided to the memory cell. A non-volatile memory cell, on the other hand, continues to retain data long after power has been removed from the memory cell. One type of non-volatile memory cell is a one-time programmable memory cell.

Conventional one-time programmable memory cells, such as fuses and antifuses, typically require a large current to either blow an element and make an open circuit (in the case of a fuse) or to lower the resistance of an element and make it conductive (in the case of an antifuse). This requirement of a large current, which may be as high as about 250 mA, in turn leads to high (and expensive) silicon die area requirement to house large transistors for driving the current and wide propagation tracks for conducting the current. Furthermore, conventional one-time programmable memory cells are typically fabricated on the silicon surface and consume silicon die area for this additional reason.

Other conventional non-volatile memory cells, such as EPROM, EEPROM and FLASH memories, are transistor-based cells that utilize a floating gate to store data in the cell. The presence of a charge on the floating gate indicates a first logic state, while the absence of a charge on the floating gate indicates a second logic state. These conventional memory cells typically require large silicon die area due to, e.g., the size of transistors needed to apply a high voltage to the memory cell. Furthermore, conventional memory cells are also typically fabricated on the silicon surface and consume silicon die area for this additional reason.

Accordingly, there is a need for memory cells which consume less silicon die area while providing the performance characteristics of conventional memory cells.

### SUMMARY

The systems and methods described herein address deficiencies in the prior art by enabling fabrication of non-volatile memory cells using micro-electromechanical (MEMS) technology. In some embodiments, MEMS-based memories utilize the position of a mechanical member to store data in the memory cell. When the mechanical member is in a first position that is spaced away from an electrode, the memory cell exhibits a first electrical property that indicates a first logic state. When the mechanical member is in a second position that contacts the electrode, the memory cell exhibits a second electrical property that indicates a second logic state. MEMS-based memories may be advantageously formed on the top surface of the interconnect layers of an integrated circuit, thereby consuming less silicon die area.

In one aspect, the systems and methods described herein provide for a one-time programmable memory having multiple memory cells. Each memory cell includes an electrode disposed within the memory cell and a conductor material having two ends disposed proximate to the electrode. The programmable memory provides means for applying a voltage between the electrode and the conductor material, e.g., a voltage source. The conductor material is physically attached to the memory cell at its two ends. The applied voltage generates an electrostatic force sufficient to alter the conductor material from a first state to a second state to program the memory cell. In some embodiments, the electrostatic force is sufficient to permanently alter the conductor material from the first state to the second state. In some embodiments, permanently altering the conductor material comprises bending the conductor material beyond a yield strength or an ultimate tensile strength of the conductor material. This may lead to permanent deformation or fracture of the conductor material. In some embodiments, the conductor material includes a metal bridge or a metal plate. In some embodiments, the conductor material of the memory cell includes one or more anchors. The conductor material is physically connected to the memory cell via the anchors. In some embodiments, the electrostatic force generates stress at the anchors in order to permanently alter the conductor material.

In some embodiments, each memory cell includes a second electrode. The programmable memory provides means for applying a second voltage between the second electrode and the conductor material, e.g., a voltage source. The second electrode may be disposed on a side of the conductor material opposite to the initial electrode. In some embodiments, the electrodes are disposed at the top and the bottom of the conductor material, respectively. The applied second voltage may generate an electrostatic force sufficient to force the conductor material into its original form, thereby reprogramming the memory cell. In some embodiments, the electrostatic force is sufficient to temporarily alter the conductor material of each memory cell from the first state to the second state. The conductor material may return to the first state after a period of time.

In some embodiments, each memory cell includes a current source for driving through the conductor material an applied current that heats the conductor material. The applied voltage and the applied current may be proportionally configured to alter the conductor material from the first state to the second state. In some embodiments, altering the conductor material changes a resistance of the conductor material, thereby altering a current flow through the conductor material when a sensing voltage is applied. In some embodiments, each memory cell is read by applying the sensing voltage between the electrode and the conductor material, and measuring the current flow through the conductor material. The current flow may be about 3 μA or lower. The applied voltage may be about 15V or lower. In some embodiments, the memory is fabricated within a MEMS device, a NEMS device, or any other suitable device.

In another aspect, the systems and methods described herein provide for trimmer device to trim or reconfigure a device or circuit, e.g., to adjust the electrical characteristics of the device or circuit. The trimmer device includes an electrode disposed within the trimmer device, a conductor material having two ends disposed proximate to the electrode, and means for applying a voltage between the electrode and the conductor material, e.g., a voltage source or any other suitable means. The conductor material is physically attached to the trimmer device at its two ends. The applied voltage generates an electrostatic force sufficient to permanently deform or fracture the conductor material such that its resistance is changed, thereby trimming or reconfiguring the circuit. In some embodiments, fracturing the conductor material changes a resistance of the conductor material, thereby altering a current flow through the conductor material when a sensing voltage is applied. In some embodiments, the conductor material includes a metal bridge or a metal plate.

In yet another aspect, the systems and methods described herein provide for a method for manufacturing a chip comprising a programmable memory arranged in an integrated circuit. The method includes producing layers that form electrical and/or electronic elements on a semiconductor material substrate followed by an Inter Level Dielectric (ILD) layer. The method further includes producing interconnection layers including an etch resistant bottom layer of conductor material and a top layer of conductor material, separated by at least one layer of dielectric material. The at least one etch resistant bottom layer of conductor material is layed over and in contact with the ILD layer. The method further includes forming a portion of the programmable memory within the interconnection layers by applying gaseous HF to the at least one layer of dielectric material. The programmable memory includes memory cells, and each memory cell includes an electrode disposed within the memory cell, a metal bridge or a metal plate disposed proximate to the electrode, and means for applying a voltage between the electrode and the one of the metal bridge and the metal plate, e.g., a voltage source. In some embodiments, the portion of the programmable memory is formed above the etch resistant bottom layer of conductor material in contact with the ILD layer.

### BRIEF DESCRIPTION OF THE DRAWINGS

Other advantages and characteristics of the systems and methods described herein may be appreciated from the following description, which provides a non-limiting description of illustrative embodiments, with reference to the accompanying drawings, in which:

FIG. 1A depicts a diagrammatic view of a one-time programmable memory cell in a first state, according to an illustrative embodiment of the invention;

FIG. 1B depicts a diagrammatic view of a one-time programmable memory cell in a second state, according to an illustrative embodiment of the invention;

FIG. 1C depicts a diagrammatic view of a one-time programmable memory cell in a third state, according to an illustrative embodiment of the invention;

FIG. 2 depicts a stress-strain curve for a conductor material, according to an illustrative embodiment of the invention;

FIG. 3A depicts a diagrammatic view of a reprogrammable memory cell in a first state, according to an illustrative embodiment of the invention;

FIG. 3B depicts a diagrammatic view of a reprogrammable memory cell in a second state, according to an illustrative embodiment of the invention;

FIG. 3C depicts a diagrammatic view of a reprogrammable memory cell in a third state, according to an illustrative embodiment of the invention;

FIG. 3D depicts a flow diagram for programming a reprogrammable memory cell, according to an illustrative embodiment of the invention;

FIG. 4 depicts a diagrammatic view of a conductor material for a memory cell in a deformed state, according to an illustrative embodiment of the invention;

FIG. 5 depicts a circuit diagram of a memory cell, according to an illustrative embodiment of the invention;

FIG. 6A depicts a cross-section after a first set of process flow steps for fabricating a programmable memory cell, according to an illustrative embodiment of the invention;

FIG. 6B depicts a cross-section after a second set of process flow steps for fabricating a programmable memory cell, according to an illustrative embodiment of the invention;

FIG. 6C depicts a cross-section after a third set of process flow steps for fabricating a programmable memory cell, according to an illustrative embodiment of the invention.

### DETAILED DESCRIPTION OF EMBODIMENTS

To provide an overall understanding of the systems and methods described herein, certain illustrative embodiments will now be described. However, it will be understood by one of ordinary skill in the art that the systems and methods described herein may be adapted and modified as is appropriate for the application being addressed and that the systems and methods described herein may be employed in other suitable applications, and that such other additions and modifications will not depart from the scope thereof.

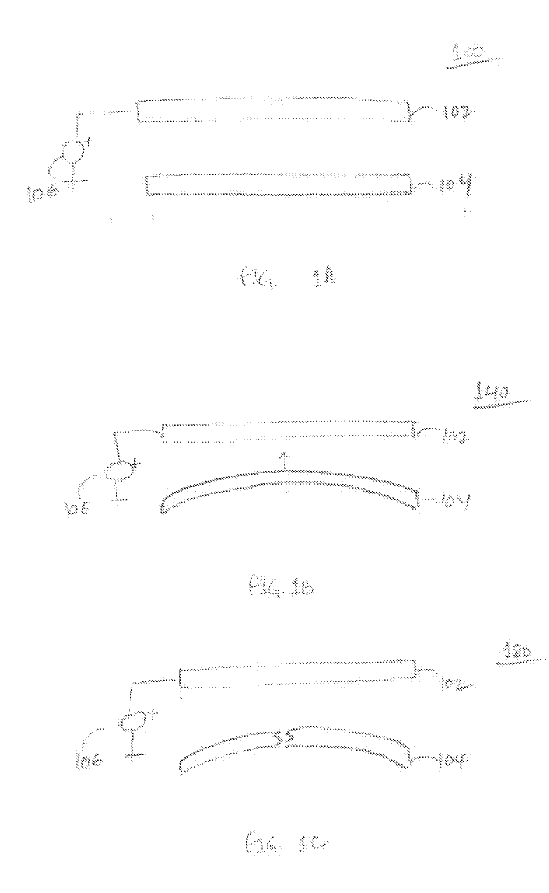

FIGS. 1A-1C depict illustrative diagrammatic views of a one-time programmable memory cell in different states. As shown in FIG. 1A, the memory cell includes an electrode 102, a conductor material 104 having two ends disposed proximate to the electrode, and a voltage source 106 for applying a voltage between the electrode and the conductor material. The conductor material is physically attached to the memory cell at its two ends via, e.g., anchors. In some embodiments, the conductor material 104 includes a metal bridge or a metal plate. In some embodiments, electrode 102 is the metal capping layer of a MEMS device.

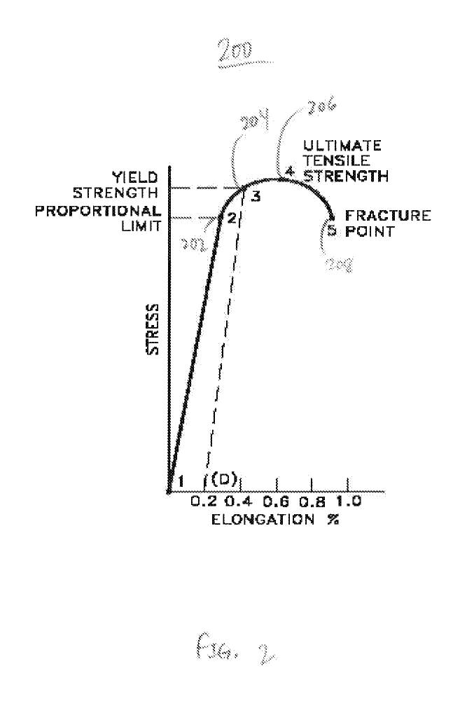

To program the memory cell, the voltage source 106 applies a voltage between the electrode 102 and conductor material 104 to generate an electrostatic force on the conductor material 104. In some embodiments, the applied voltage is about 15V in magnitude. The electrostatic force is applied such that the conductor material is pulled towards to the electrode 102 until it is permanently altered, e.g., either fractured or permanently deformed, as shown in FIG. 1B. The electrostatic force causes stress on the conductor material 104 until the stress exceeds a yield strength or an ultimate tensile strength of the conductor material. Further details on the yield strength and the ultimate tensile strength are described with respect to FIG. 2 below. FIG. 1C shows an illustrative embodiment of the memory cell where the electrostatic force causes a fracture in the conductor material, thereby changing its resistance and programming the memory cell.

Permanently altering the conductor material via fracture or deformation, i.e., programming the memory cell, may change the resistance of the conductor material. As a result, when a sensing voltage is applied to the memory cell before and after programming, the resulting current flow may be different. This resulting current flow may be used as an indication of the logic state or value (zero or one) stored in the memory cell. In some embodiments, the applied current is about 3 μA in magnitude. Alternatively, when a sensing current is applied to the conductor material before and after programming, the resulting voltage in the memory cell may be different. This resulting voltage may be used as an indication of the logic state or value (zero or one) stored in the memory cell.

In some embodiments, the memory cell includes means for driving a current through the conductor material, e.g., a current source, to aid the electrostatic force in permanently altering the conductor material. The current heats the conductor material making it more susceptible to deformation. This may lower the voltage applied to generate the electrostatic force, thereby reducing the required size of the voltage source. In some embodiments, the current is adjusted to heat the conductor material, reducing the strength of the conductor material and, thereby, making the conductor material less resistant to the electrostatic force used to alter the physical state of the conductor material. The proportion of voltage applied and current applied may vary or be adjustable. For example, if a higher voltage is applied (resulting in a higher electrostatic force), then a lower current can be applied (resulting in less heating) or vice versa.

FIG. 2 depicts an illustrative stress-strain curve for the conductor material described with respect to FIGS. 1A-1C. The stress-strain curve 200 is a graphical representation of the relationship between stress, derived from measuring the electrostatic force applied on the conductor material, and strain, derived from measuring the deformation of the conductor material, i.e. elongation. In the embodiment shown, the conductor material is a metal typically used in CMOS processes. For example, conductor material may include aluminum, copper, titanium, and/or titanium nitride. The conductor material may include a stack-up of different sublayers typically found in CMOS processes. The material generally exhibits a linear stress-strain relationship up to a well defined point 202. The linear portion of the curve is the elastic region. After the point 202, as deformation continues, the stress increases on account of strain hardening, passes the yield strength 204, and reaches the ultimate tensile strength 206. However, beyond this point 206, the local cross-sectional area where the electrostatic force is applied decreases more quickly than the rest of the conductor material resulting in an increase in the true stress until the conductor material fractures at fracture point 208.

The yield strength is typically determined by the “offset yield method,” by which a line is drawn parallel to the linear elastic portion of the curve and intersecting the abscissa at some arbitrary value (generally from 0.1% to 0.2%). The intersection of this line and the stress-strain curve is considered to be the yield strength point 204. The elastic region till yield strength point 204 is the portion of the curve where the material will return to its original shape if the load is removed. The plastic region beyond yield strength point 204 is the portion where some permanent deformation will occur, even if the electrostatic force is removed. The conductor material fractures when the curve reaches fracture point 208.

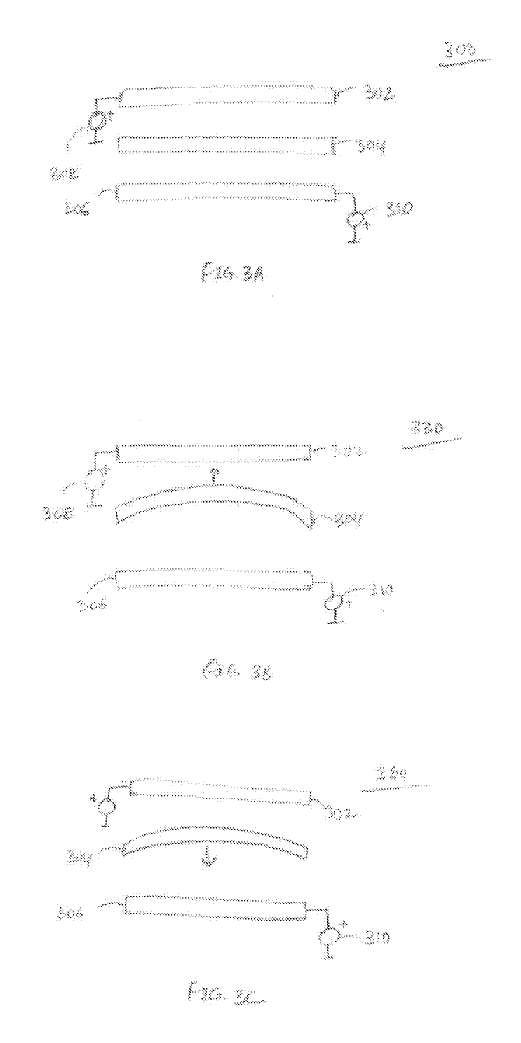

FIG. 3A-3C depict illustrative diagrammatic views of a reprogrammable memory cell in different states. The memory cell (shown in FIG. 3A) includes an electrode 302, a conductor material 304 having two ends disposed proximate to the electrode, an electrode 306, and voltage sources 308 and 310. The conductor material is physically attached to the memory cell at its two ends via, e.g., anchors. In some embodiments, the conductor material 304 includes a metal bridge or a metal plate. In some embodiments, electrode 302 is the metal capping layer of a MEMS device. In some embodiments, electrode 310 is a metal layer disposed within a MEMS device.

In order to program or switch the current logic state of the memory cell, the voltage source 308 applies a voltage between the electrode 302 and conductor material 304 to generate an electrostatic force on the conductor material 304. In some embodiments, the applied voltage is about 15V in magnitude. The electrostatic force is applied such that the conductor material is pulled towards to the electrode 302 until it is permanently altered, e.g., permanently deformed, as shown in FIG. 3B. The electrostatic force causes stress on the conductor material 304 until the stress exceeds a yield strength of the conductor material and enters the plastic region of the conductor material. Even after the electrostatic force is removed, the conductor material 304 does not return to its original shape and remains deformed. The deformed state of the conductor material 304 results in a change in its resistance, and the memory cell is considered programmed. For example, the electrostatic force may program the logic state of the memory cell from zero to one. As a result, when a sensing voltage is applied to the memory cell before and after programming, the resulting current flow may be different. This resulting current flow may be used as an indication of the logic state or value (zero or one) stored in the memory cell. In some embodiments, the applied current is about 3 μA in magnitude. Alternatively, when a sensing current is applied to the conductor material 304 before and after programming, the resulting voltage in the memory cell may be different. This resulting voltage may be used as an indication of the logic state or value (zero or one) stored in the memory cell.

Compared to the memory cell of FIGS. 1A-1C, the memory cell of FIGS. 3A-3C includes the additional electrode 306 disposed on a side of the conductor material opposite to the electrode 302, and includes the additional voltage source 310. The additional components make the memory cell reprogrammable, if needed. In order to reprogram or flip the current logic state of the memory cell, the voltage source 310 applies a voltage between the electrode 306 and conductor material 304 to generate an electrostatic force on the conductor material 304. In some embodiments, the applied voltage is about 15V in magnitude. As shown in FIG. 3C, the electrostatic force is applied such that the conductor material is pulled towards the electrode 306 until it is permanently altered, e.g., permanently deformed. The electrostatic force causes stress on the conductor material 304 until the stress exceeds a yield strength of the conductor material and enters the plastic region of the conductor material. As a result, once the electrostatic force is removed, the conductor material 304 returns to its original shape as shown in FIG. 3A. This returns the resistance of conductor material 304 to its original value, and the memory cell is considered reprogrammed. For example, the electrostatic force may flip the logic state of the memory cell from one to zero. When a sensing voltage is applied to the memory cell after programming, the resulting current flow may be used as an indication of the logic state or value stored in the memory cell. In some embodiments, the applied current is about 3 μA in magnitude. Alternatively, when a sensing current is applied to the conductor material 304 after programming, the resulting voltage in the memory cell may be used as an indication of the logic state or value stored in the memory cell.

In some embodiments, the memory cell includes means for driving a current through the conductor material, e.g., a current source, to aid the electrostatic force in permanently altering the conductor material. The current heats the conductor material making it more susceptible to deformation. This may lower the voltage applied to generate the electrostatic force, thereby reducing the required size of the voltage source. In some embodiments, the current is adjusted to heat the conductor material, reducing the strength of the conductor material and, thereby, making the conductor material less resistant to the electrostatic force used to alter the physical state of the conductor material. The proportion of voltage applied and current applied may vary or be adjustable. For example, if a higher voltage is applied (resulting in a higher electrostatic force), then a lower current can be applied (resulting in less heating) or vice versa.

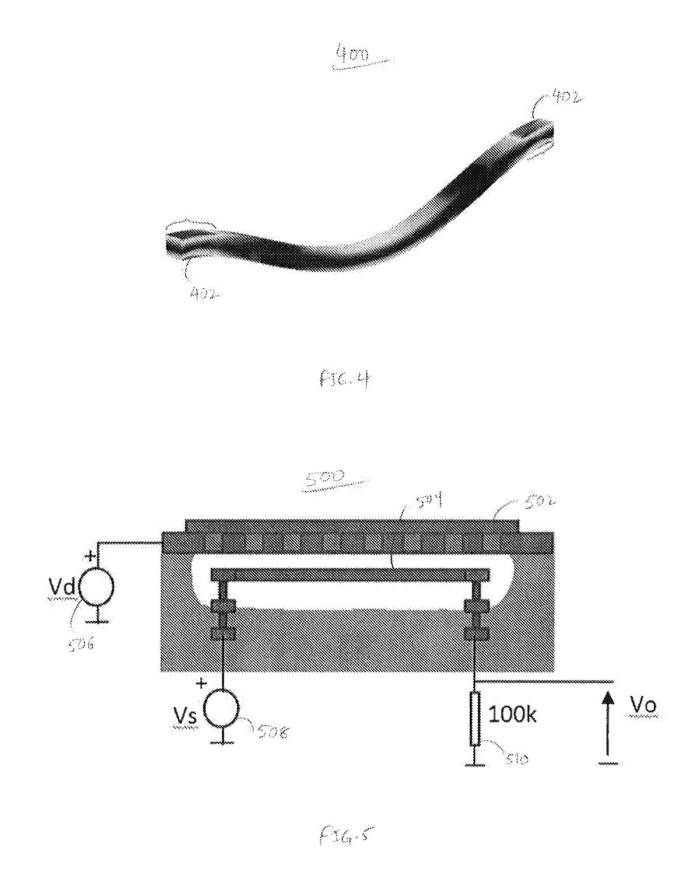

FIG. 3D depicts an illustrative flow diagram 390 for programming the reprogrammable memory cell of FIGS. 3A-3C. Though flow diagram 390 is described with respect to FIGS. 3A-3C, the steps may be equally applicable to programming a one-time programmable memory cell as described with respect to FIGS. 1A-1C. At step 391, a voltage source applies voltage to the memory cell such that a conductor material within the cell is pulled towards an electrode. The change in shape of the conductor material results in a change in resistance of the conductor material. At step 392, this resistance is measured via a measuring circuit (e.g., the circuit described with respect to FIG. 5 below), and at step 393, a deformation or displacement of the conductor material is determined based on the measured resistance. At step 394, the determined displacement of the conductor material is compared with a threshold displacement for permanent deformation (or fracture in case of a one-time programmable memory cell), and the electrostatic force continues until the threshold displacement is reached. For example, the threshold displacement may correspond to a yield strength or an ultimate tensile strength as described with respect to FIG. 2 above. Steps 392 and 394 are repeated until permanent alteration of the conductor material is reached, thereby changing its resistance, and programming the memory cell. At step 395, the memory cell is considered programmed and the voltage source is disconnected. In some embodiments, steps 391-395 are repeated in order to reprogram a reprogrammable memory cell, e.g., to flip its logic state from one to zero.

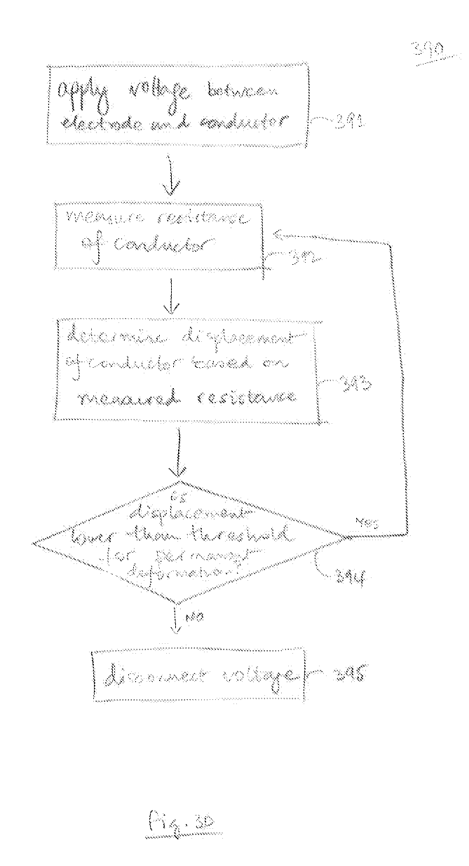

FIG. 4 depicts an illustrative diagrammatic view of a conductor material 400 for a memory cell in a deformed state. The conductor material includes anchors 402. The conductor material is physically connected to the memory cell via the anchors 402. An electrostatic force applied on conductor material 400 (as described with respect to FIGS. 1A-1C above) generates stress at one or both anchors 402 in order to permanently alter the conductor material. Conductor material 400 may bend or fracture at one or both anchors 402 as a result of the stress due to the electrostatic force.

FIG. 5 depicts an illustrative circuit diagram of a memory cell 500. The memory cell 500 includes an electrode 502, a conductor material 504 disposed proximate to the electrode, and voltage sources 506 and 508. The conductor material is physically attached to the memory cell at its two ends via, e.g., anchors. In the embodiment shown, the conductor material 504 includes a metal bridge disposed within MEMS device, and electrode 502 is the metal capping layer of the MEMS device. The memory cell further includes a pull down resistor 510, which is used when determining the logic state or value stored in the memory cell.

In order to program the memory cell, the voltage source 506 applies a driving voltage (Vd) between the electrode 502 and conductor material 504 to generate an electrostatic force on the conductor material 504. In some embodiments, the applied voltage is about 15V in magnitude. The electrostatic force is applied such that the conductor material is pulled towards to the electrode 502 until it is permanently altered, e.g., either fractured or permanently deformed. The alteration changes the resistance of the conductor material, thereby programming the memory cell.

To determine the logic state or value stored in the memory cell, voltage source 508 applies a sensing voltage (Vs). In some embodiments, the applied voltage is about 1V in magnitude. Output voltage (Vo) across resistor 510 is measured to determine the logic state or value of the memory cell. In some embodiments, the output voltage (Vo) across resistor 510 is about 0V (indicating a fractured conductor material) or about 1V (indicating the conductor material is unaltered). In this embodiment, the measured voltage across resistor 510 is based on a ratio between the resistance of the conductor material 504 (e.g., about 10Ω or any other suitable resistance) and the resistor 510 (e.g., about 100 kΩ or any other suitable resistance).

The proposed memory cell configuration requires significantly less silicon die area for implementation compared to a conventional programmable memory. For example, a conventional antifuse implemented in a 0.4 μm process may require a driving current of about 250 mA and a corresponding transistor size of about 50 μm×50 μm and a propagation track having a width of about 250 μm. However, the proposed memory cell configuration implemented in a 0.4 μm may operate using a driving current of only about 3 μA, with a corresponding transistor size of only about 5 μm×5 μm, and with a propagation track having a width of only about 0.4 μm. Therefore, the proposed memory cell and driving circuitry substantially reduce the silicon die area compared to conventional programmable memories.

In some embodiments, the memory cell described with respect FIGS. 1A-1C or FIGS. 3A-3C is used as trimmer device to trim or reconfigure a device or circuit, e.g., to adjust the electrical characteristics of the device or circuit. The trimmer device includes an electrode disposed within the trimmer device, a conductor material having two ends disposed proximate to the electrode, and means for applying a voltage between the electrode and the conductor material, e.g., a voltage source or any other suitable means. The conductor material is physically attached to the trimmer device at its two ends. The applied voltage generates an electrostatic force sufficient to permanently deform or fracture the conductor material such that its resistance is changed, thereby trimming or reconfiguring the circuit.

Described below are process flow steps for fabricating a programmable memory cell via a CMOS MEMS-based process. For example, the memory cell may be fabricated using a CMOS MEMS-based process described in commonly-owned U.S. Patent Application Publication No. 2010/0295138, entitled “Methods and Systems for Fabrication of MEMS CMOS Devices.” However, fabrication processes for the memory need not be limited to CMOS MEMS-based processes, and may include MEMS-based processes, NEMS-based processes, and other suitable processes.

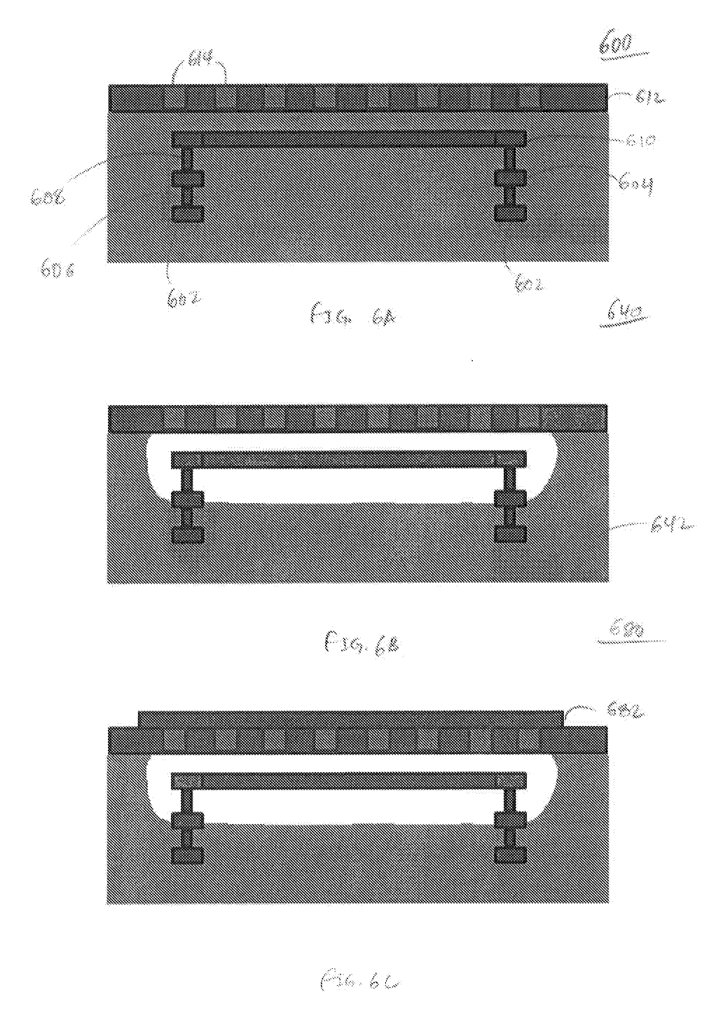

FIG. 6A depicts a cross-section after a first set of process flow steps for fabricating a programmable memory cell. The thickness of the layers has been magnified. In one embodiment, the memory cell is fabricated using a standard CMOS process. In one embodiment, the memory cell is fabricated in a cavity formed within interconnection layers of a CMOS chip. In an alternative embodiment, the memory cell is fabricated as a stand-alone MEMS device. Initially a metal layer is deposited. The metal layer can be made from, e.g., AlCu metal alloy. A masking layer is deposited above the metal layer, and then the metal layer is etched using, e.g., dry HF, to form plates 602. An Inter Metal Dielectric (IMD) layer is deposited above plates 602, followed by a masking layer, and then the IMD layer is etched and filled with metal to form spacers or vias 604. In one embodiment, the IMD layer includes a layer of non-doped oxide. Another metal layer is deposited, followed by a masking layer deposited above the metal layer, and then the metal layer is etched using, e.g., dry HF, to form plates 606. Another IMD layer is deposited above plates 606, followed by a masking layer, and then the IMD layer is etched and filled with metal to form spacers or vias 608. Plates 602 and 604 and spacers 606 and 608 together form anchors for the memory cell. A metal layer is deposited on spacers 608 to form bridge 610 of the memory cell. Another IMD layer is deposited on bridge 610, followed by top metal layer 612. A masking layer is deposited on top metal layer 612. Top metal layer 612 is then etched to form through-holes 614. The through-holes can allow passage of etchant, e.g., vapor HF, to etch material below top metal layer 612.

FIGS. 6B and 6C depict cross-sections after a second and a third set of process flow steps, respectively, for fabricating the memory cell. An etchant, e.g., dry HF, is released via through-holes 614 in top metal layer 612. The etchant etches away portions of the IMD layers to release the anchors and bridge of the memory cell, as shown in FIG. 6B. Bottom plates 602 are buried in the remaining oxide 642 of IMD layers to provide support to the memory cell. Finally, metallization layer 682 is deposited on top metal layer 612 to seal the memory cell from the outside environment, as shown in FIG. 6C. In one embodiment, the memory cell is fabricated using MEMS-based, NEMS-based, or MEMS CMOS-based integrated chip technology.

In some embodiments, a programmable memory is arranged in an integrated circuit. The process flow steps of FIGS. 6A-6C are performed in the interconnection layers of the integrated circuit. Layers that form electrical and/or electronic elements on a semiconductor material substrate are produced and then overlaid by an Inter Level Dielectric (ILD) layer. Interconnection layers including an etch resistant bottom layer of conductor material and a top layer of conductor material, separated by at least one layer of dielectric material, are produced such that the at least one etch resistant bottom layer of conductor material is layed over and in contact with the ILD layer. A portion of the programmable memory is formed within the interconnection layers by applying gaseous HF to the at least one layer of dielectric material in accordance with the process flow steps described with respect to FIGS. 6A-6C. The programmable memory includes memory cells, and each memory cell includes an electrode disposed within the memory cell and a metal bridge or a metal plate disposed proximate to the electrode. The programmable memory provides means for applying a voltage between the electrode and the one of the metal bridge and the metal plate, e.g., a voltage source. In some embodiments, the portion of the programmable memory is formed above the etch resistant bottom layer of conductor material in contact with the ILD layer.

Applicants consider all operable combinations of the embodiments disclosed herein to be patentable subject matter. Those skilled in the art will know or be able to ascertain using no more than routine experimentation, many equivalents to the embodiments and practices described herein. For example, though the fabrication of a memory cell is described with respect to FIGS. 6A-6C, the embodiments and practices may be equally applicable to fabrication of a trimmer device or any other suitable device. Accordingly, it will be understood that the systems and methods described herein are not to be limited to the embodiments disclosed herein, but is to be understood from the following claims, which are to be interpreted as broadly as allowed under the law. It should also be noted that, while the following claims are arranged in a particular way such that certain claims depend from other claims, either directly or indirectly, any of the following claims may depend from any other of the following claims, either directly or indirectly to realize any one of the various embodiments described herein.

What is claimed is:

1. A programmable memory, comprising:
a plurality of memory cells, each memory cell comprising:
an electrode disposed within the memory cell;
a conductor material having two ends disposed proximate to the electrode, wherein the conductor material is physically attached to the memory cell at the two ends;
a voltage source for applying a voltage between the electrode and the conductor material;
wherein the applied voltage generates an electrostatic force sufficient to alter the conductor material from a first state to a second state to program the memory cell.

2. The memory of claim 1, wherein the electrostatic force is sufficient to permanently alter the conductor material from the first state to the second state.

3. The memory of claim 2, wherein permanently altering the conductor material comprises bending the conductor material beyond one of a yield strength and an ultimate tensile strength of the conductor material.

4. The memory of claim 2, wherein permanently altering the conductor material comprises fracturing the conductor material.

5. The memory of claim 2, wherein permanently altering the conductor material comprises bending the conductor material such that the conductor material is permanently deformed but not fractured.

6. The memory of claim 5, further comprising:
at least one memory cell comprising a second electrode; and
a second voltage source for applying a voltage between the second electrode and the conductor material.

7. The memory of claim 6, wherein the second electrode is disposed on a side of the conductor material opposite to the electrode, wherein the applied second voltage generates an electrostatic force sufficient to force the conductor material into its original form, thereby reprogramming the memory cell.

8. The memory of claim 1, wherein the conductor material comprises at least one anchor, wherein the conductor material is physically connected to the memory cell via the at least one anchor.

9. The memory of claim 8, wherein the electrostatic force generates stress at the at least one anchor in order to permanently alter the conductor material.

10. The memory of claim 1, wherein the conductor material comprises one of a metal bridge and a metal plate.

11. The memory of claim 1, wherein each memory cell comprises a current source for driving an applied current through the conductor material, wherein the current heats the conductor material.

12. The memory of claim 11, wherein the applied voltage and the applied current are proportionally configured to alter the conductor material from the first state to the second state.

13. The memory of claim 1, wherein altering the conductor material changes a resistance of the conductor material, thereby altering a current flow through the conductor material when a sensing voltage is applied.

14. The memory of claim 13, wherein each memory cell is read by applying the sensing voltage between the electrode and the conductor material, and measuring the current flow through the conductor material.

15. The memory of claim 13, wherein the current flow is about 3 μA or lower.

16. The memory of claim 1, wherein the applied voltage is about 15V or lower.

17. The memory of claim 1, wherein the memory is fabricated within one of a MEMS device and a NEMS device.

18. The memory of claim 1, wherein the electrostatic force is sufficient to temporarily alter the conductor material from the first state to the second state.

19. The memory of claim 18, wherein the conductor material returns to the first state after a period of time.

20. A method for manufacturing a chip comprising a programmable memory arranged in an integrated circuit comprising:
producing layers that form electrical and/or electronic elements on a semiconductor material substrate followed by an Inter Level Dielectric (ILD) layer,
producing interconnection layers comprising at least one etch resistant bottom layer of conductor material and a top layer of conductor material, separated by at least one layer of dielectric material, the at least one etch resistant bottom layer of conductor material being layed over and in contact with the ILD layer, and
forming at least a portion of the programmable memory within the interconnection layers by applying gaseous HF to the at least one layer of dielectric material, wherein the programmable memory comprises a plurality of memory cells, each memory cell comprising an electrode disposed within the memory cell and one of a metal bridge and a metal plate disposed proximate to the electrode, and a voltage source for applying a voltage between the electrode and the one of the metal bridge and the metal plate.

21. The method of claim 20, wherein the portion of the programmable memory is formed above the etch resistant bottom layer of conductor material in contact with the ILD layer.

22. A trimmer device for reconfiguring a circuit, comprising:
an electrode disposed within the trimmer device;
a conductor material having two ends disposed proximate to the electrode, wherein the conductor material is physically attached to the trimmer device at the two ends;
a voltage source for applying a voltage between the electrode and the conductor material;
wherein the applied voltage generates an electrostatic force sufficient to fracture the conductor material, thereby reconfiguring the circuit.

23. The device of claim 22, wherein fracturing the conductor material changes a resistance of the conductor material, thereby altering a current flow through the conductor material when a sensing voltage is applied.

24. The device of claim 22, wherein the conductor material comprises one of a metal bridge and a metal plate.
